(19) United States
(12) Patent Application Publication
(10) Pub. No.: US 2016/0021781 A1
(43) Pub. Date: Jan. 21, 2016

(54) THERMAL INTERFACE DEVICE WITH MICROPOROUS SEAL CAPABLE OF PREVENTING THE MIGRATION OF THERMAL GREASE

(71) Applicant: THALES, Courbevoie (FR)

(72) Inventors: Pierre JOUANNE, FAYENCE (FR); Silvain LEGRAND, NICE (FR); Olivier DAMIANO, LES ADRETS DE L'ESTEREL (FR)

(21) Appl. No.: 14/797,059

(22) Filed: Jul. 10, 2015

(30) Foreign Application Priority Data
Jul. 18, 2014 (FR) 14 01617

(51) Int. Cl. H05K 7/20; B23P 15/26; B32B 38/10; B32B 3/26; B32B 7/04; B32B 7/12; B32B 7/02; B32B 27/32; B32B 27/20; B32B 37/00; B32B 37/12; B32B 37/22; B32B 38/08; B29C 65/48; B29C 65/00; F28F 13/18

(52) U.S. Cl. CPC H05K 7/2039; F28F 13/18; B23P 15/26; B32B 38/10; B32B 3/26; B32B 7/045; B32B 7/12; B32B 7/02; B32B 27/322; B32B 27/20; B32B 37/0076; B32B 37/12; B32B 37/223; B32B 38/08; B29C 65/48; B29C 66/032; B29C 66/41; B29C 66/71; B29C 66/727; B32B 2255/10; B32B 2305/026; B32B 2307/302; B32B 2307/202; B32B 2327/18; B32B 2581/00; B32B 2605/18; B29K 2627/18

(57) ABSTRACT

A thermal interface device comprises a film of thermal grease intended to be inserted between a first object and a second object, and a microporous seal encircling the periphery of the film of thermal grease. A manufacturing method comprises steps of: deposition of the microporous seal on the first object in such a way as to form a closed frame on the first object; deposition of the thermal grease on the first object, inside the closed frame; smoothing of the thermal grease bearing on the frame of microporous seal, making it possible to form the film of thermal grease encircled by the microporous seal; and deposition of the second object on the film of thermal grease.

### CROSS-REFERENCE TO RELATED APPLICATION

This application claims priority to foreign French patent application No. FR 1401617, filed on Jul. 18, 2014, the disclosure of which is incorporated by reference in its entirety.

### FIELD OF THE INVENTION

The present invention relates to the field of thermal interface materials, more specifically it relates to the implementation of a thermal grease encircled by a microporous seal making it possible to limit the phenomena of migration, or pump out, of the thermal grease. The invention is particularly useful in the aerospace field for fixing dissipative equipment on a bearing structure.

### BACKGROUND

The thermal interface materials, also known by the acronym TIM, are used to promote heat exchanges between an equipment item generating or transporting heat and a bearing structure. Several types of thermal interface material are known, in particular the thermal greases. A thermal grease generally comprises a binder, such as, for example, a silicone-coated polymer, and a filler promoting the heat transfer. In a known example, metal particles of boron oxide are dispersed in a silicone-coated polymer matrix of polydimethylsiloxane, or PDMS, type.

The thermal greases are notably implemented to promote the discharge of heat from electronic circuit boards, such as computer processors. Heat dissipation is also a particular difficulty in the aerospace field, on the one hand because of the strong temperature variations encountered by the satellite during its mission, and on the other hand because of the absence of gaseous atmosphere limiting the heat exchanges with the outside of the satellite. In a known architecture of a satellite in Earth orbit, a bearing structure is made up of panels, for example sandwich panels of aluminium or carbon composite materials. Various dissipative equipment items can be fixed onto its panels, such as, for example, electronic modules which generate heat, or heat sinks which transmit heat. Thermal greases are thus implemented at the interface between these equipment items and the panels to promote the transfer of heat between the components.

This implementation does, however, come up against a number of difficulties that the present invention seeks to resolve. A first difficulty relates to the phenomena of migration of the thermal grease, also known as pump out. Since dissipative equipment items and the bearing structure are made of different materials, they exhibit generally different thermomechanical behaviours. The temperature oscillations for example linked to the thermal cyclings of the satellite in orbit generate a relative movement of the dissipative equipment items and of the structure which leads to a migration of the grease and degrades the thermal interface between the equipment item and the structure.

A second difficulty that is observed is the drying of the thermal grease, or dry out. The progressive drying of the grease at the periphery of the interface modifies its thermomechanical properties and thereby also degrades the thermal interface between the equipment item and the structure.

A third difficulty encountered relates to venting, during the launching of the satellite out of the atmosphere or during a degassing operation for vacuum applications. The expulsion of air bubbles trapped in the thermal grease generates a vent and drives some of the thermal grease out of the interface.

In a first approach, attempts have been made to resolve these difficulties by arranging an elastomer seal at the periphery of the thermal grease. The principle and the limitations of this approach are illustrated by FIG. 1. A thermal interface 10, inserted between a structure 11 and a dissipative equipment item 12, comprises a thermal grease 13 and an elastomer seal 14 arranged over a part of the periphery of the thermal grease. The elastomer seal, in contact with the structure 11 and the dissipative equipment item 12, ensures the seal-tightness between these components and the thermal grease, making it possible to limit the phenomena of pump out and dry out of the interface. The elastomer seal is impermeable to the gases. It is therefore necessary to provide a path to allow for the discharging of the air bubbles, or venting, from the thermal grease to the outside. The elastomer seal cannot therefore surround the thermal grease over its entire periphery. On the contrary, the interface includes a vent 15 by which the thermal grease is in contact with the outside, allowing for the degassing of the thermal grease through the vent 15. This first approach suffers however from a number of limitations. The pump out and dry out phenomena remain possible through the vent. As illustrated by the figure, a quantity of thermal grease may be driven under the effect of the thermal cyclings out of the interface through the vent, degrading the thermomechanical efficiency of the interface. The significant delay in polymerization of the elastomer seal (several days) or the complexity of the application of the elastomer seal at the periphery of the thermal grease also constitute notable industrial limitations.

In a second approach described by the patent application published under the reference U.S. Pat. No. 6,121,680, attempts have been made to resolve these difficulties by trapping the thermal grease in a fabric. This approach makes it possible to limit the phenomenon of pump out of the grease trapped in the links of the fabric but does not resolve the problem of dry out of the thermal grease at its periphery.

Thus, the thermal interface materials envisaged in the known state of the art remain limited by the phenomena of migration of the greases, of dry out and of degassing. It remains desirable to have a thermal interface material capable of ensuring a heat transfer in a durable manner, while supporting the particularly severe stresses of aerospace, and notably the phenomena of pump out, dry out and of venting. The thermal interface material retained will moreover have to allow for a simple industrial deployment, notably by allowing an accurate and reproducible dosage of the thermal grease.

### SUMMARY OF THE INVENTION

To this end, the subject of the invention is a thermal interface device comprising a film of thermal grease intended to be inserted between a first object and a second object, and a microporous seal encircling the periphery of the film of thermal grease.

Advantageously, the microporous seal is oil-repelling and permeable to air. In other words, the microporous seal is configured so as to trap the thermal grease, or in other words prevent the migration or pump out, while being permeable to air, or, in other words, while allowing the venting or degassing.

Advantageously, the microporous seal comprises microporous film of polytetrafluoroethylene.

Advantageously, the microporous seal includes an electrically conductive filler.

Advantageously, the thermal grease comprises a binder and a thermally conductive filler promoting the heat transfer, the average diameter of the pores of the microporous seal being less than the average diameter of the filler so as to prevent the migration of the thermally conductive filler.

Advantageously, the microporous seal exhibits a friction coefficient greater than 0.25.

Advantageously, the microporous seal has a thickness of between 150 and 180 μm.

The invention relates also to a mircoporous seal comprising, on one face, an adhesive film and a mould-stripping film; the mould-stripping film being able to be removed to allow said face of the microporous seal to adhere to one of the two objects by means of the adhesive film.

Advantageously, the microporous seal comprises, on one face, an adhesive tape that can be removed so as to allow said face of the microporous seal to be placed in contact with one of the two objects.

The invention relates also to an equipment item comprising a first object, a second object and a thermal interface device having the features described previously, inserted between the first object and the second object.

The invention relates also to a method for manufacturing said equipment item, characterized in that it comprises steps consisting in:
depositing the microporous seal on the first object, placing a first face of the microporous seal in contact with the first object, and in such a way as to form a closed frame on the first object,
depositing thermal grease on the first object, inside the closed frame of microporous seal,
smoothing the thermal grease by means of a smoothing tool bearing on the frame of microporous seal, making it possible to form the film of thermal grease encircled by the microporous seal, and
depositing the second object on the film of thermal grease, placing a second face of the microporous seal at least partially in contact with the second object.

Advantageously, the method comprises a subsequent step of mounting fixing means between the first object and the second object.

Advantageously, the method comprises a preliminary step consisting in removing a mould-stripping film from the microporous seal, so as to uncover a face of the microporous seal comprising an adhesive film, the next step of deposition of the microporous seal placing the adhesive film in contact with the first object.

Advantageously, the step of removal of the mould-stripping film and the step of deposition of the microporous seal on the first object are performed simultaneously by means of a roll pay-out device.

Advantageously, the method comprises, on completion of the step of smoothing of the thermal grease, a step of removal of an adhesive tape previously arranged on a face of the microporous seal.

### BRIEF DESCRIPTION OF THE DRAWINGS

The invention will be better understood and other advantages will become apparent on reading the detailed description of an embodiment given by way of example in the following figures.

FIG. 1, already presented, represents a thermal interface device inserted between a substrate and a dissipative equipment item according to the known state of the art,

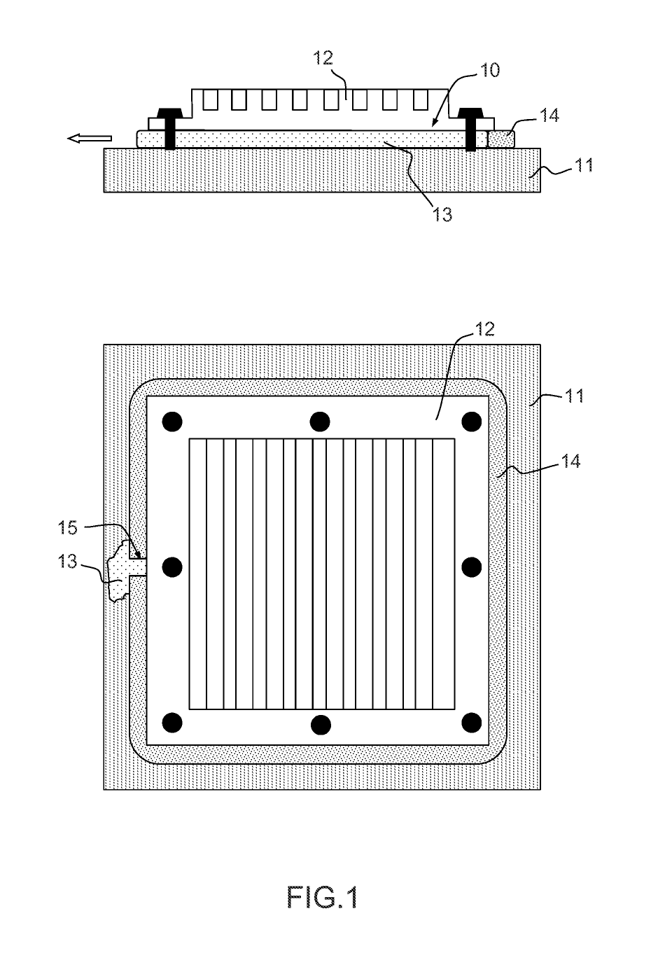

FIG. 2 represents an example of a thermal interface device according to the invention, inserted between a substrate and a dissipative equipment item,

FIGS. 3a-3d illustrate the steps of a first exemplary method for manufacturing an equipment item comprising a thermal interface device according to the invention inserted between a substrate and a dissipative equipment item,

FIGS. 4a-4g illustrate the steps of a second exemplary method for manufacturing an equipment item comprising a thermal interface device according to the invention inserted between a substrate and a dissipative equipment item,

FIG. 5 illustrates a particular implementation of a microporous seal in a roll pay-out device for the production of a thermal interface device according to the invention.

In the interests of clarity, the same elements will bear the same references in the different figures.

### DETAILED DESCRIPTION

The general idea of the invention is to have a microporous seal at the periphery of a film of thermal grease. The microporous seal encircles the film of thermal grease over its entire periphery. The microporous seal is oil-repelling and permeable to air so that it traps the thermal grease, or in other words prevents migration or pump out, while being permeable to the gas, or in other words allows the venting or degassing.

The duly constructed thermal interface device is particularly suited to an aerospace application. In this sense, the thermal interface device detailed hereinbelow is intended to be inserted between a substrate, i.e. the bearing structure, and a dissipative equipment item such as an electronic module or a heat exchanger. It is obvious that the invention is not limited to this particular application in the aerospace field. Generally, the invention relates to a thermal interface device comprising a film of thermal grease intended to be inserted between a first object and a second object, and a microporous seal encircling the periphery of the film of thermal grease. In the figures, the first object corresponds to the substrate and the second object corresponds to the dissipative equipment item.

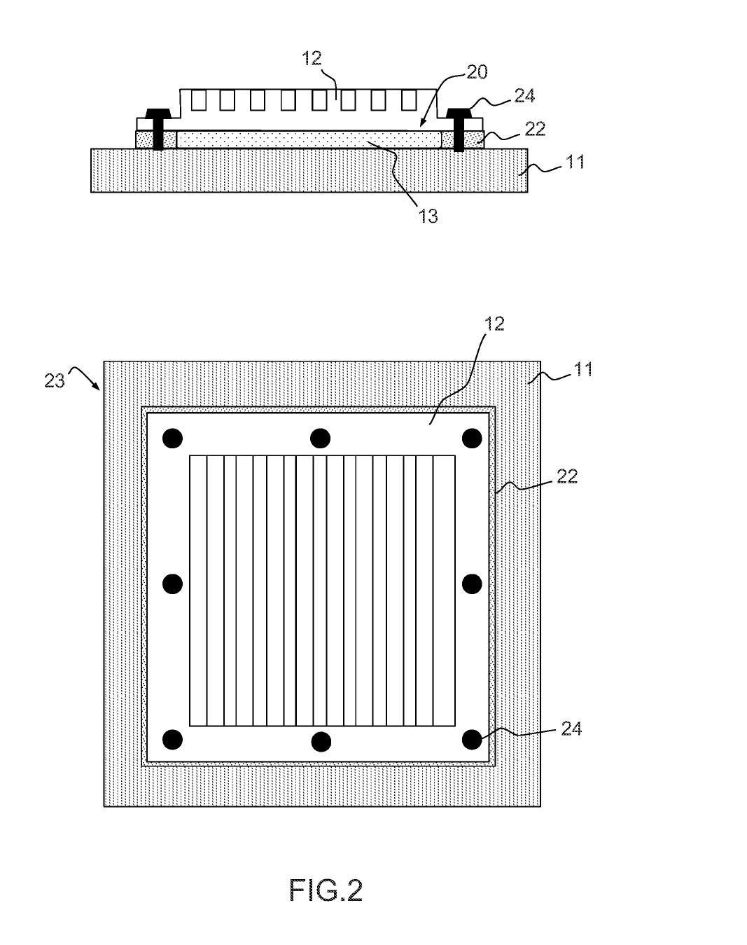

FIG. 2 represents an exemplary thermal interface device according to the invention, inserted between a substrate and a dissipative equipment item. Thus, the thermal interface device 20 comprises a film of thermal grease 13 surrounded over its entire periphery by a microporous seal 22. The thermal interface device 20 ensures the mechanical securing and the heat transfer between a substrate 11 and a dissipative equipment item 12. The invention relates to the thermal interface device 20 and to an equipment item 23 comprising the substrate 11, the dissipative equipment item 12 and the thermal interface device 20. The equipment item 23 can also comprise fixing means 24 between the substrate and the dissipative equipment item. The fixing means can be arranged in such a way as to pass through or not pass through the microporous seal or the film of thermal grease.

Contrary to the solutions previously described from the known prior art, the film of thermal grease is entirely surrounded, in other words encircled, by the seal. Since the microporous seal 22 is advantageously permeable to gas, it is not necessary to form an opening to allow the venting of the thermal grease. The discharging of any air bubbles trapped in the thermal grease, upon the launching of the satellite or in the venting operation, is done through pores of the microporous barrier formed by the seal 22. Contrary to the known solutions, the thermal grease then remains trapped inside the microporous barrier. The thermal interface device is thus freed of the phenomena of migration or pump out, as well as the phenomena of dry out of the thermal grease.

Note that in the interests of legibility FIG. 2 represents a microporous seal with outer dimensions slighter greater than the outer dimensions of the dissipative equipment item. This representation is only one possible exemplary implementation. In an alternative implementation, the microporous seal is adjusted to the outer dimensions of the dissipative equipment item.

In a particular implementation of the invention, the microporous seal is made up of a microporous film of polytetrafluoroethylene, or PTFE. It has pores of an average diameter of the order of 5 μm. It is oil-repelling, water-repelling and permeable to air. The microporous film of PTFE advantageously supports temperatures greater than 150° C. in operation and greater than 200° C. at peak. It is further advantageously chemically compatible with all of the chemical constituents of the equipment item (adhesives, grease, solvent, etc.).

As a variant, the microporous seal comprises a microporous film of polyetherimide or PEI, of polyethersulfone PES or of polyimide or PI.

The microporous seal can advantageously be configured in such a way as to exhibit a high electrical conductivity, by the addition of conductive filler to its polymer matrix, such as nanoparticles of carbon. Thus, the thermal interface device ensures a grounding of the dissipative equipment item without requiring any dedicated components such as, for example, a metal braid.

As specified previously, a thermal grease generally comprises a binder, such as, for example, a silicone-coated polymer, and a filler promoting the heat transfer. This filler is a thermally conductive filler. Advantageously, the microporous seal is configured so as to prevent the migration of the filler. In other words, the average diameter of the pores of the microporous seal is advantageously less than the average diameter of the heat-conducting filler so as to prevent the migration of the filler, that is to say the “pump out” of the filler. The filler typically has a diameter of between 20 μm and 40 μm.

Advantageously, the microporous seal has pores whose average diameter is between 1 μm and 10 μm.

The microporous seal can also advantageously be configured in such a way as to exhibit a friction coefficient greater than 0.25. The microporous seal therefore opposes the relative slippage of the dissipative equipment item relative to the substrate, making it possible to lower the mechanical securing requirements of the fixing means.

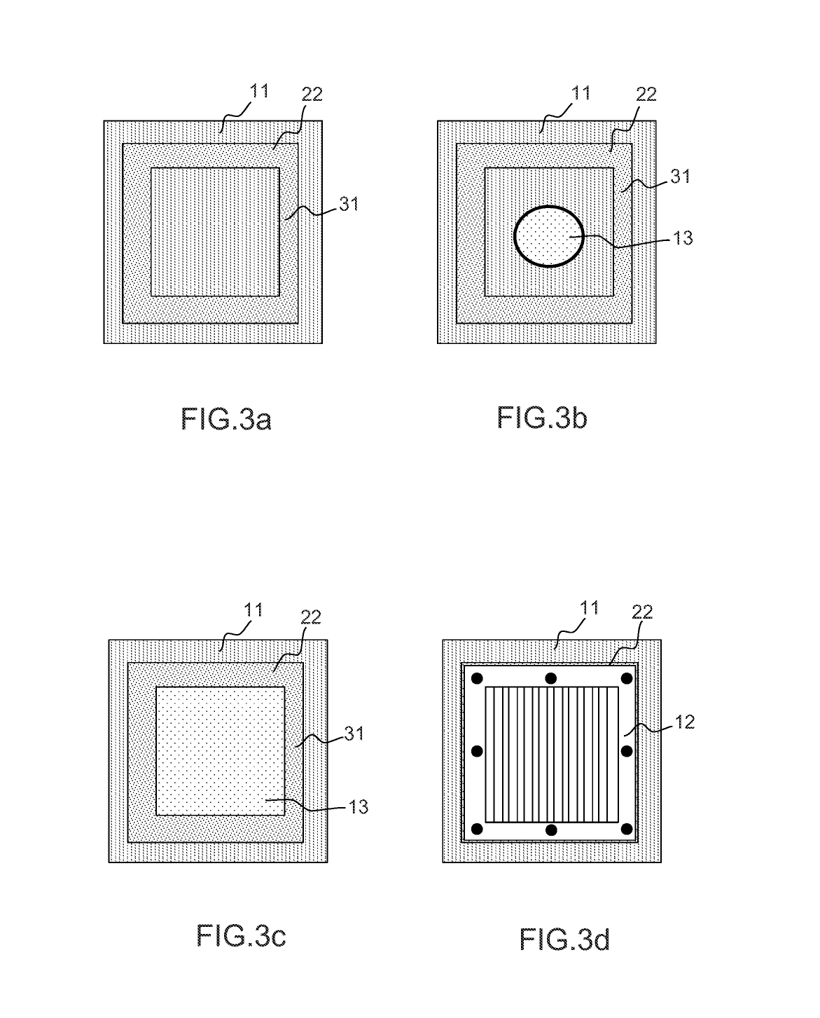

FIGS. 3a-3d illustrate the steps of a first exemplary method for manufacturing an equipment item comprising a thermal interface device according to the invention inserted between a substrate and a dissipative equipment item. In this first example, the manufacturing method comprises four steps, illustrated by means of the four diagrams (a), (b), (c) and (d) representing the equipment item in plan view.

The manufacturing method thus comprises:
a first step (a), consisting in depositing the microporous seal 22 on the substrate 11, placing a first face 30 of the microporous seal 22 in contact with the substrate 11, and in such a way as to form a closed frame 31 on the substrate,
a second step (b) consisting in depositing a bead of thermal grease 13 on the substrate 11, inside the closed frame 31 formed by the microporous seal 22,
a third step (c) consisting in smoothing the thermal grease 13 by means of a smoothing tool (not represented) bearing on the frame 31, making it possible to form the film of thermal grease 13 encircled by the microporous seal 22, and
a fourth step (d) consisting in depositing the dissipative equipment item 12 on the film of thermal grease 13, placing a second face 32 of the microporous seal 22 in contact with the dissipative equipment item 12.

This exemplary manufacturing method is particularly advantageous. It makes it possible to trap the thermal grease inside the closed frame, making it possible to accurately adjust the thickness of thermal grease on completion of the smoothing step. The quantity of thermal grease implemented and the thermomechanical properties of the duly constructed thermal interface can be easily controlled. The gauging of the thickness of the film of thermal grease, by means of a microporous seal of controlled thickness, typically of the order of 150 to 180 μm, advantageously makes it possible to absorb the flatness defects of the substrate and/or of the dissipative equipment item, while ensuring an optimized heat exchange between these two components. As a variant, the thickness of the seal lies outside of this preferred interval.

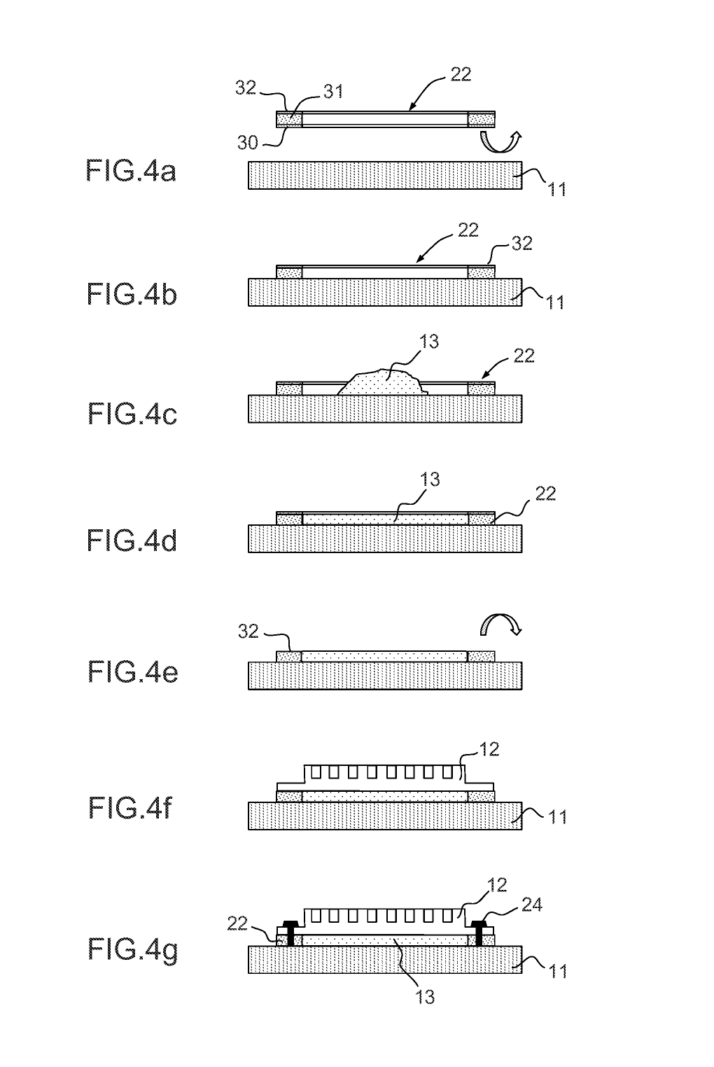

FIGS. 4a-4g illustrate the steps of a second exemplary method for manufacturing an equipment item comprising a thermal interface device according to the invention, inserted between a substrate and a dissipative equipment item. In this second example, the method comprises seven steps, illustrated by means of the seven diagrams (a′) to (g′) representing the equipment item in side view. This second example comprises the four steps described by means of FIGS. 3a-3d. Typically, the diagrams (b′), (c′), (d′) and (f′) in side view in FIGS. 4a-4g correspond respectively to the diagrams (a), (b), (c) and (d) in plan view in FIGS. 3a-3d. This second exemplary method also comprises three additional steps illustrated by the diagrams (a′), (e′) and (g′) that will now be detailed.

As described previously the microporous film 22 comprises a first face 30, intended to come into contact with the substrate by forming a closed frame 31 thereon and a second face 32 intended to come into contact with the dissipative equipment item, after the deposition and smoothing of the thermal grease inside the closed frame 31.

In a particular implementation, the first face 30 is adhesive-treated to allow the closed frame 31 to be placed and secured on the substrate, for example by means of an acrylic or silicone transfer adhesive. Advantageously, the microporous seal can comprise, on its first face 30, an adhesive film deposited on the PTFE film and a mould-stripping film protecting the adhesive film before the step of deposition of the microporous seal on the substrate. In other words, the method can comprise a preliminary step, illustrated by the diagram (a′), consisting in removing the mould-stripping film from the microporous seal, so as to uncover the face 30 provided with the adhesive film. The subsequent step of deposition of the microporous seal on the substrate, illustrated by the diagram (b′), then places the adhesive film of the seal in contact with the substrate.

According to a similar principle, the second face 32 can advantageously comprise an adhesive tape, also called liner, allowing for the smoothing of the thermal grease without clogging of the micropores of the microporous film. Advantageously, the tape is very lightly adhesive-treated so as to allow its removal after the step of smoothing of the thermal grease, without damaging, by lifting, the microporous film deposited on the substrate. In other words, the method can comprise a step, illustrated by the diagram (e′), consisting in removing the adhesive tape previously arranged on the second face of the microporous seal allowing for the smoothing of the thermal grease without clogging of the microporous seal.

Finally, the method can also comprise a subsequent step, illustrated by the diagram (g′), of the mounting of fixing means 24 between the substrate and the dissipative equipment item.

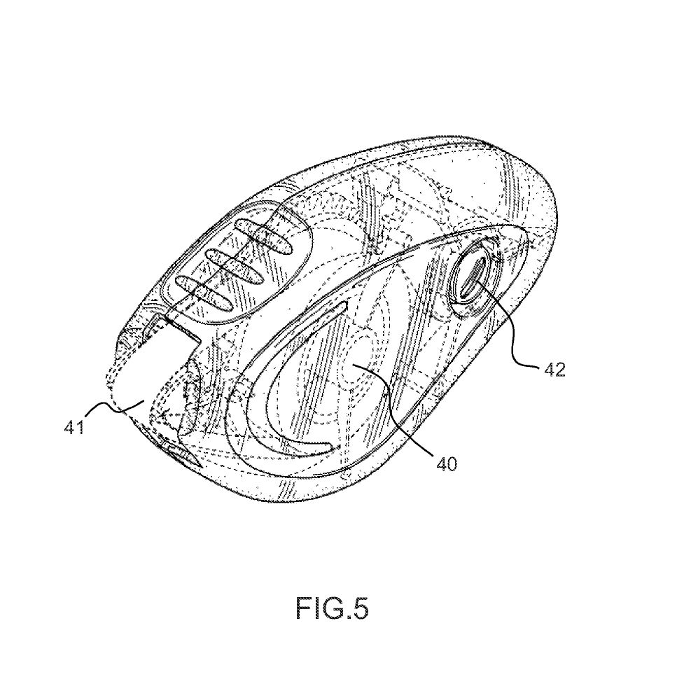

FIG. 5 illustrates a particular implementation of a microporous seal in a roll pay-out device for the production of a thermal interface device according to the invention. This type of pay-out well known in the paper industry can advantageously be implemented in the context of the present invention to simplify the step of deposition of the microporous film and the formation of the closed frame 31 along a previously marked outline. In this case, the step of removal of the mould-stripping film illustrated by the diagram (a′) and the step of deposition of the microporous seal on the substrate—illustrated by the diagram (b′)—are performed simultaneously by means of the roll pay-out device. Typically, the microporous seal is wound onto a first roll 40. It is deposited on the substrate by means of the nose 41; the mould-stripping film being simultaneously removed from the adhesive-treated face 31 of the microporous film and wound onto a second roll 42.

1. A thermal interface device, comprising: a film of thermal grease intended to be inserted between a first object and a second object, and a microporous seal encircling the periphery of the film of thermal grease.

2. The thermal interface device according to claim 1, in which the microporous seal is oil-repelling and permeable to air.

3. The device according to claim 1, in which the microporous seal comprises a microporous film of polytetrafluoroethylene.

4. The device according to claim 1, in which the microporous seal includes an electrically conductive filler.

5. The device according to claim 1, in which the thermal grease comprises a binder and a thermally conductive filler promoting the heat transfer, the average diameter of the pores of the microporous seal being less than the average diameter of the filler so as to prevent the migration of the thermally conductive filler.

6. The device according to claim 1, in which the microporous seal exhibits a friction coefficient greater than 0.25.

7. The device according to claim 1, in which the microporous seal has a thickness of between 150 and 180 μm.

8. A microporous seal of a thermal interface device according to claim 1, further comprising, on one face, an adhesive film and a mould-stripping film; the mould-stripping film being able to be removed to allow said face of the microporous seal to adhere to one of the two objects by means of the adhesive film.

9. The microporous seal of a thermal interface device according to claim 1, further comprising, on one face, an adhesive tape that can be removed so as to allow said face of the microporous seal to be placed in contact with one of the two objects.

10. An equipment item comprising a first object and a second object, further comprising a thermal interface device according to claim 1 inserted between the first object and the second object.

11. A method for manufacturing an equipment item according to claim 10, further comprising:
depositing the microporous seal on the first object, placing a first face of the microporous seal in contact with the first object, and in such a way as to form a closed frame on the first object, depositing thermal grease on the first object, inside the closed frame of microporous seal, smoothing the thermal grease by means of a smoothing tool bearing on the frame of microporous seal, making it possible to form the film of thermal grease encircled by the microporous seal, and depositing the second object on the film of thermal grease, placing a second face of the microporous seal at least partially in contact with the second object.

12. The method according to claim 11, comprising a subsequent step of mounting fixing means between the first object and the second object.

13. The method according to claim 11, comprising a preliminary step consisting in removing a mould-stripping film from the microporous seal, so as to uncover a face of the microporous seal comprising an adhesive film, the next step of deposition of the microporous seal placing the adhesive film in contact with the first object.

14. The method according to claim 13, in which the step of removal of the mould-stripping film and the step of deposition of the microporous seal on the first object are performed simultaneously by means of a roll pay-out device.

15. The method according to claim 11, comprising on completion of the step of smoothing of the thermal grease, a step of removal of an adhesive tape previously arranged on a face of the microporous seal.
